(19) United States
(12) Patent Application Publication
(10) Pub. No.: US 2009/0011580 A1
(43) Pub. Date: Jan. 8, 2009

(54) METHOD FOR FABRICATING SEMICONDUCTOR MEMORY DEVICE

(75) Inventor: Se-Kyoung CHOI, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/963,919

(22) Filed: Dec. 24, 2007

(30) Foreign Application Priority Data
Jul. 2, 2007 (KR) 10-2007-0066134

(51) Int. Cl. H01L 21/425

(52) U.S. Cl. 438/524; 257/E21.473

(57) ABSTRACT

A method for fabricating a semiconductor memory device includes forming a channel region in a substrate, selectively etching the substrate to form a first trench, performing an impurity ion implantation process on the channel region, and etching a lower portion of the first trench to form a second trench.

### CROSS-REFERENCE TO RELATED APPLICATIONS

The present invention claims priority of Korean patent application number 10-2007-0066134, filed on Jul. 2, 2007, which is incorporated by reference in its entirety.

### BACKGROUND OF THE INVENTION

The present invention generally relates to a semiconductor fabricating technology, and more particularly, to a method for fabricating a nonvolatile memory device having a high voltage component.

A NAND flash memory is a nonvolatile memory device having a plurality of unit strings in which a plurality of cells are serially connected for high integration. The NAND flash memory is widely applied to, for example, a memory stick, a universal serial bus (USB) driver, and a hard disk.

In fabricating the NAND flash memory, a shallow trench isolation (STI) trench for device isolation is formed and an ion implantation process is performed on an exposed channel region of a substrate. This is done for compensating a reduction in doping concentration of the channel region because impurity ions implanted into the channel region for adjusting a threshold voltage are diffused into a device isolation structure subsequently buried in the trench.

The ion implantation process for compensating the reduced doping concentration of the channel region is performed after forming the STI trench in a peripheral region, for example, a region where a memory cell driver such as a decoder and a page buffer is formed.

In the conventional method for fabricating a NAND flash memory, however, impurity ions are more implanted into a lower portion than sidewalls of the trench because the ion implantation process for compensating the doping concentration of the channel region is performed after forming the STI trench in the substrate. This causes the reduction in breakdown voltage of a high voltage transistor having a relatively high operation range of more than 15 V among transistors formed in the peripheral region. Consequently, the reduction in the breakdown voltage of the high voltage transistor may degrade characteristics of the semiconductor memory device.

### SUMMARY OF THE INVENTION

The present invention contemplates a method for fabricating a semiconductor memory device having a cell region and a peripheral region where a high voltage component will be formed. A shallow trench isolation (STI) process and an impurity ion implantation process for compensating the reduction in doping concentration of a channel region are performed, thereby reducing a concentration in a lower portion of a trench in which the high voltage component will be formed.

In accordance with an aspect of the present invention, there is provided a method for fabricating a semiconductor memory device which includes forming a channel region in a substrate, selectively etching the substrate to form a first trench, performing an impurity ion implantation process on the channel region, and etching a lower portion of the first trench to form a second trench.

In accordance with another aspect of the present invention, there is provided a method for fabricating a semiconductor memory device having a cell region and a high voltage region. The method includes preparing a substrate having channel regions defined in the cell region and in the high voltage region, respectively, selectively etching the substrate to form first trenches in the cell region and the high voltage region, performing an impurity ion implantation process on the channel regions, and etching lower portions of the first trenches to form second trenches.

### BRIEF DESCRIPTION OF THE DRAWINGS

FIGS. 1A to 1E illustrate a method for fabricating a semiconductor memory device in accordance with an embodiment of the present invention.

### DETAILED DESCRIPTION OF THE PREFERRED EMBODIMENTS

Hereinafter, a method for fabricating a semiconductor memory device in accordance with the present invention will be described in detail with reference to the accompanying drawings. In the figures, the dimensions of layers and regions are exaggerated for clarity of illustration. It will also be understood that when a layer is referred to as being over another layer or substrate, it can be directly over the other layer or substrate, or intervening layers may also be present. Like reference numerals refer to like elements throughout the drawings. Alphabetic reference symbols refer to the same layers partially modified through an etching or polishing process.

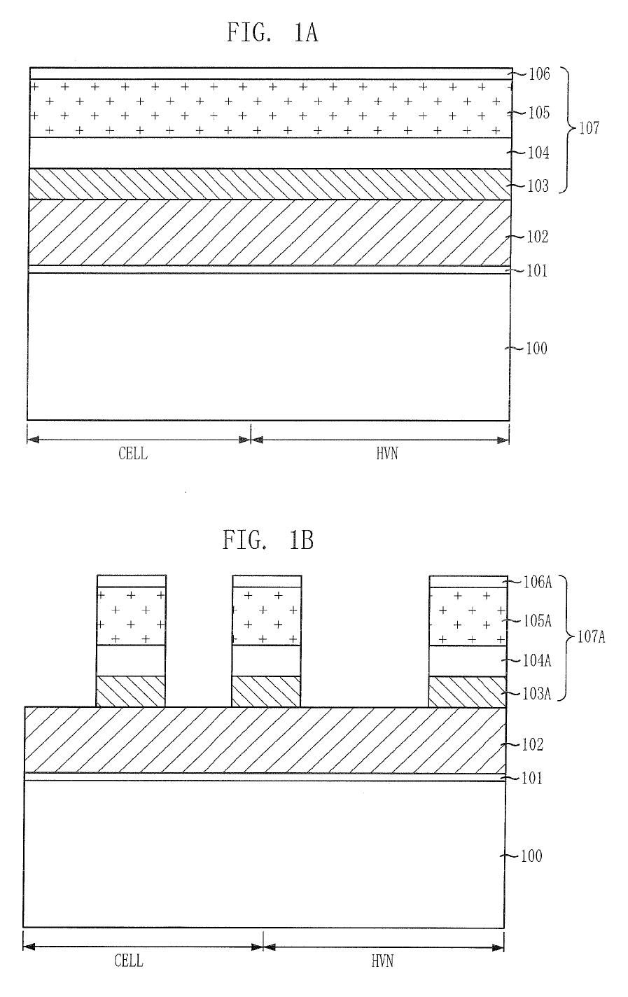

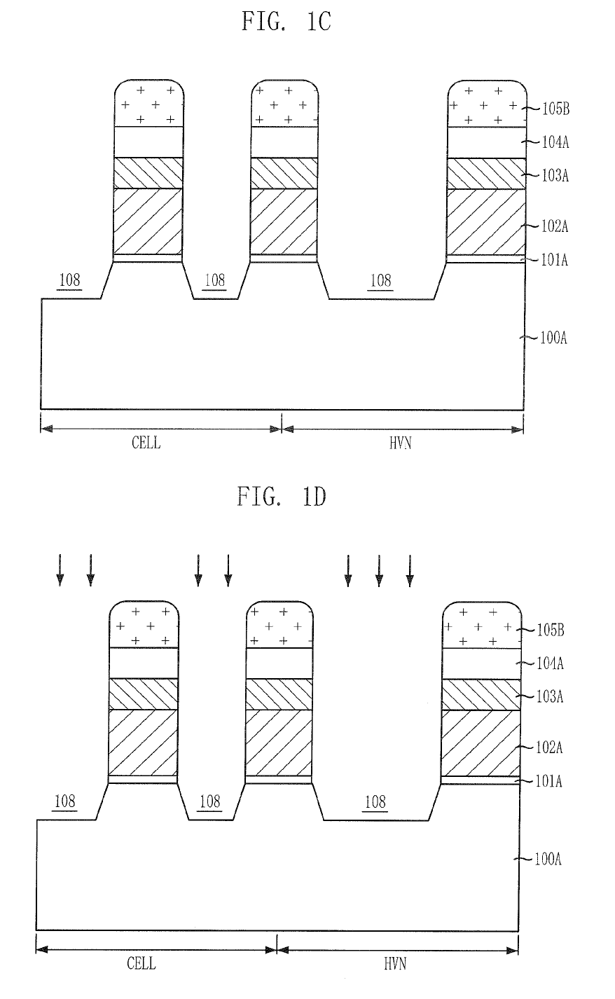

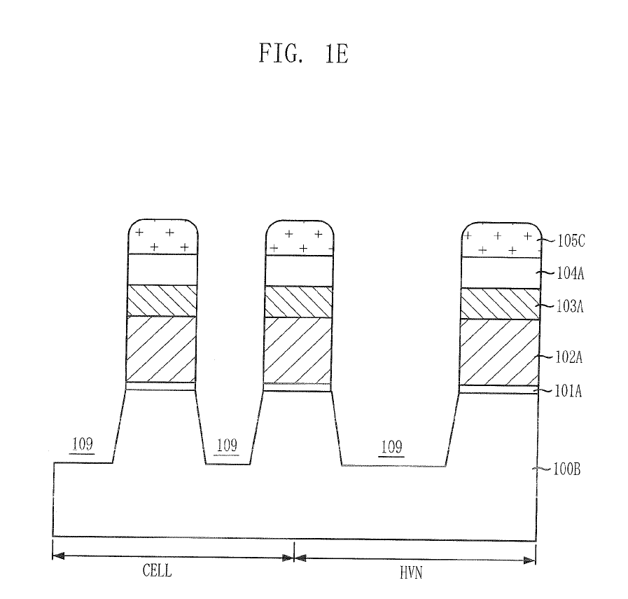

FIGS. 1A to 1E illustrate a method for fabricating a semiconductor memory device in accordance with an embodiment of the present invention. Specifically, a method for fabricating a NAND flash memory using an advanced self aligned-shallow trench isolation (ASA-STI) process is illustrated. The NAND flash memory has a cell region CELL and a high voltage region HVN where a high voltage component such as an NMOS transistor will be formed.

Referring to FIG. 1A, a triple n-type well (not shown) and p-type well (not shown) are formed in a substrate 100, e.g., a p-type substrate.

An impurity ion implantation process for adjusting a threshold voltage is performed on a cell region CELL and a high voltage region HVN. The impurity ion implantation process may be performed on the cell region CELL after performing on the high voltage region HVN, or may be performed on the high voltage region HVN after performing on the cell region CELL.

For example, the impurity ion implantation process for adjusting the threshold voltage in the cell region CELL may be performed by using boron fluoride (BF) at an ion implantation energy ranging from approximately 10 KeV to approximately 30 KeV and a dose ranging from approximately 1.0×10¹³ ions/cm² to approximately 5.0×10¹³ ions/cm². The impurity ion implantation process for adjusting a threshold voltage in the high voltage region HVN may be performed by using boron (B) at an ion implantation energy ranging from approximately 30 KeV to approximately 70 KeV and a dose ranging from approximately 7.0×10¹¹ ions/cm² to approximately 11.0×10¹³ ions/cm².

A tunneling dielectric layer 101 where Fouler-Nordheim (F-N) tunneling occurs is formed over the substrate 100. The tunneling dielectric layer 101 may be formed of oxide, e.g., silicon oxide (SiO₂). A thermal treatment using N₂ gas may be performed to form a nitride layer in an interface between the silicon oxide layer and the substrate 100. The tunneling dielectric layer 101 may be formed of high-k dielectric layer such as a metal oxide layer, e.g., an aluminum oxide layer (Al₂O₃), a hafnium oxide layer (HfO₂), a zirconium oxide layer (ZrO₂), a stacked layer thereof, or a mixed layer thereof. The tunneling dielectric layer 101 may be formed to a thickness ranging from approximately 50 [symbol] to approximately 100 [symbol] . When the tunneling dielectric layer 101 is formed of silicon oxide, a dry oxidation process, a wet oxidation process, or an oxidation process using radical ion may be used. In view of characteristics, it is preferable to perform the dry oxidation process and the wet oxidation process, instead of the oxidation process using the radical ions. The thermal treatment using the N₂ gas may be performed in a furnace.

A conductive layer 102 for a floating gate is formed over the tunneling dielectric layer 101. The conductive layer 102 may be formed of a conductive material to a thickness ranging from approximately 320 Å to approximately 550 Å. For example, the conductive layer 102 includes one selected from the group consisting of polycrystalline silicon, transition metal, rare-earth metal, and an alloy layer, and a combination thereof. The polycrystalline silicon includes un-doped polycrystalline silicon or doped polycrystalline silicon, or both. When the polycrystalline silicon is the un-doped polycrystalline silicon, impurity ions are separately implanted through a subsequent ion implantation process. The polycrystalline silicon layer is formed by using a low pressure chemical vapor deposition (LPCVD) process. In this case, silane (SiH₄) gas is used as a source gas, and phosphine (PH₃) gas, boron trichloride (BH₃), or diborane (B₂H₆) gas is used as a doping gas. Examples of the transition metal include iron (Fe), cobalt (Co), tungsten (W), nickel (Ni), palladium (Pd), platinum (Pt), molybdenum (Mo), and titanium (Ti). Examples of the rare-earth metal include erbium (Er), yttrium (Y), lanthanum (La), cerium (Ce), terbium (Tb), dysprosium (Dy), holmium (Ho), thulium (Tm), and lutetium (Lu).

A buffer layer (not shown) may be formed over the conductive layer 102. The buffer layer is formed for preventing the damage of the conductive layer 102 from being damaged in a subsequent process of depositing and removing a hard mask 107. The buffer layer may be formed of a material having a high etch selectivity with respect to the hard mask 107. For example, the buffer layer (not shown) is formed of silicon oxide (SiO₂) when the hard mask 107 is formed of silicon nitride (Si₃N₄).

The hard mask 107 may be formed over the buffer layer (not shown). The hard mask 107 may include a nitride layer 103, an oxide layer 104, an amorphous carbon layer 105, and a silicon oxide nitride (SiON) layer 106. The hard mask 107 may be formed of a single nitride layer, a nitride/oxide layer, or a nitride/amorphous carbon/silicon oxide nitride layer.

The nitride layer 103 may be formed of a silicon nitride (Si₃N₄) layer to a thickness ranging from approximately 400 [symbol] to approximately 600 [symbol] , preferably approximately 500 [symbol] . The oxide layer 104 may be formed of a silicon oxide (SiO₂) layer to a thickness ranging from approximately 1,200 [symbol] to approximately 1,600 [symbol] , preferably 1,400 [symbol] . The amorphous carbon layer 105 may be formed to a thickness ranging from approximately 2,000 [symbol] to approximately 3,000 [symbol] , preferably approximately 2,500 [symbol] . The silicon oxide nitride layer 106 may be formed to a thickness ranging from approximately 200 [symbol] to approximately 400 [symbol] , preferably approximately 300 [symbol] .

A photoresist pattern (not shown) is formed over the hard mask 107. The photoresist pattern has openings that are locally defined in the cell region CELL and the peripheral region including the high voltage region HVN. The number of the openings may be appropriately changed according to the degree of integration of the semiconductor memory device. A larger number of the openings are densely formed in the cell region CELL relative to the peripheral region. Further, the opening is formed to have a larger width in the peripheral region than in the cell region CELL.

Referring to FIG. 1B, a hard mask pattern 107A is formed by etching the hard mask 107 using the photoresist pattern as an etch mask. The hard mask pattern 107A includes a nitride layer pattern 103A, an oxide layer pattern 104A, an amorphous carbon layer pattern 105A, and a silicon oxide nitride (SiON) layer pattern 106A. The etching process is performed in-situ by changing the etch gas. The silicon oxide nitride layer 106, the amorphous carbon layer 105, the oxide layer 104, and the nitride layer 103 are etched at a time. Alternatively, after the silicon oxide nitride layer 106 and the amorphous carbon layer 105 are etched, the photoresist pattern is removed and the oxide layer 104 and the nitride layer 103 are etched by using the amorphous carbon pattern 105A as an etch stop layer.

Although not shown, the nitride layer 103 can serve as an etch stop layer in the process of etching the hard mask 107. This is because the conductive layer 102 may be damaged if the oxide layer 104 and the amorphous carbon layer 105 are simultaneously etched as they are relatively thick. Therefore, the etching is stopped on the nitride layer 103 by using the nitride layer 103 as an etch stop layer. Further, an overetching may be performed so that the oxide layer 104 may not remain over the nitride layer 103.

Referring to FIG. 5C, the photoresist pattern is removed. This process may remove the silicon oxide nitride layer pattern 106A (see FIG. 1B) and the amorphous carbon layer pattern 105B together by performing an ashing process using an oxygen plasma. Alternatively, the silicon oxide nitride layer pattern 106A and the amorphous carbon layer pattern 105B may remain to a given thickness in order to ensure an etching margin in the etching process.

A first trench 108 is formed by partially etching the conductive layer 102, the tunneling dielectric layer 101, and the substrate 100 using the amorphous carbon layer pattern 105B, the oxide layer pattern 104A, and the nitride layer pattern 103A as an etch stop layer. At this point, after the conductive layer 102 is etched, the tunneling dielectric layer 101 and the substrate 100 are etched. In this case, a cleaning process may be further performed after etching the conductive layer 102 and after etching the tunneling dielectric layer 101, respectively. Reference numerals 102A, 100A and 100A represents the tunneling dielectric layer, the conductive layer and the substrate, respectively, after partially etching the conductive layer 102, the tunneling dielectric layer 101 and the substrate 100 to form the first trench 108. The cleaning process may be performed in a mixed solution of H₂SO₄ and H₂O₂ (H₂SO₄:H₂O₂=4:1) at approximately 120° C. for approximately ten minutes, and then performed in a mixed solution of NH₂OH, H₂O₂, and H₂O(NH₄OH:H₂O₂:H₂O=1:4:20) at approximately 205° C. for approximately ten minutes.

The first trench 108 is formed more thinly than a target depth, preferably approximately half of the target depth, more preferably ranging from approximately one fifth to approximately half of the target depth.

The first trench 108 has a greater width in the peripheral region than that in the cell region CELL. In the case of a NAND flash memory, the first trench 108 is formed in a line type in the cell region CELL in order to define a line-type active region.

Referring to FIG. 1D, an impurity ion implantation process is performed for compensating the doping concentration of the channel region with respect to the cell region CELL and the high voltage region HVN. For example, the impurity ion implantation process may be performed by using boron (B), in a blanket process without forming an ion implantation mask, at an ion implantation energy ranging from approximately 20 KeV to approximately 40 KeV, preferably at approximately 30 KeV, and a dose ranging from approximately 0.5×10¹¹ ions/cm² to approximately 1.5×10¹² ions/cm², preferably approximately 0.5×10¹² ions/cm². In this case, an ion implantation tilt angle ranges from approximately 10° to approximately 30°, preferably approximately 15°. Under these conditions, the impurity ion implantation process is performed four times while rotating the substrate approximately 45°, 135°, 225°, and 315°.

Referring to FIG. 1E, the substrate 100A below the first trench 108 (see FIG. 1D) is etched by using the amorphous carbon layer pattern 105B, the oxide layer pattern 104A, and the nitride layer pattern 103A as an etch stop layer, thereby forming a second trench 109. The second trench 109 is formed by further removing the ion implantation region formed below the first trench 108 by the impurity ion implantation process of FIG. 1D, to a certain thickness. Reference numerals 105C and 100B represent remaining amorphous carbon pattern and substrate, respectively, after performing etching process on the amorphous carbon pattern 105B and the substrate 100A to form the second trench 109.

Since subsequent processes are identical to the typical processes, their detailed description will be omitted.

Although the ASA-STI process has been described, the present invention can also be applied to a self aligned floating gate (SAFG) process and a self aligned-STI (SA-STI) process.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A method for fabricating a semiconductor memory device, the method comprising:
forming a channel region in a substrate;
selectively etching the substrate to form a first trench;
performing an impurity ion implantation process on the channel region; and
etching a lower portion of the first trench to form a second trench.

2. The method as recited in claim 1, wherein the impurity ion implantation process is performed by using boron (B) at an ion implantation energy ranging from approximately 20 KeV to approximately 40 KeV and a dose ranging from approximately 0.5×10¹¹ ions/cm² to approximately 1.5×10¹² ions/cm².

3. The method as recited in claim 2, wherein the impurity ion implantation process is performed at an ion implantation tile angle ranging from approximately 10° to approximately 30°.

4. The method as recited in claim 2, wherein the impurity ion implantation process is performed four times while rotating the substrate approximately 45°, 135°, 225°, and 315°.

5. The method as recited in claim 1, wherein the second trench has a depth at which the impurity ions implanted into the lower portion of the first trench, by the impurity ion implantation process are removed.

6. A method for fabricating a semiconductor memory device having a cell region and a high voltage region, the method comprising:
preparing a substrate having channel regions defined in the cell region and in the high voltage region, respectively;
selectively etching the substrate to form first trenches in the cell region and the high voltage region;
performing an impurity ion implantation process on the channel regions; and
etching lower portions of the first trenches to form second trenches in the cell region and the high voltage region.

7. The method as recited in claim 6, wherein the impurity ion implantation process is performed by using boron (B) at an ion implantation energy ranging from approximately 20 KeV to approximately 40 KeV and a dose ranging from approximately 0.5×10¹¹ ions/cm² to approximately 1.5×10¹² ions/cm².

8. The method as recited in claim 6, wherein the impurity ion implantation process is performed at an ion implantation tile angle ranging from approximately 10° to approximately 30°.

9. The method as recited in claim 6, wherein the impurity ion implantation process is performed four times while rotating the substrate approximately 45°, 135°, 225°, and 315°.

10. The method as recited in claim 6, wherein the second trenches have a depth at which impurity ions implanted into the low portions of the first trenches by the impurity ion implantation process are removed.

11. The method as recited in claim 6, wherein the forming of the first trenches comprises:
forming a tunneling dielectric layer, a conductive layer for a floating gate, and a hard mask over the substrate;
etching the hard mask to form a hard mask pattern; and
selectively etching the conductive layer, the tunneling dielectric layer, and the substrate using the hard mask pattern as an etch mask.

12. The method as recited in claim 11, wherein the impurity ion implantation process is performed by using the hard mask as an ion implantation mask.

13. The method as recited in claim 11, wherein the forming of the second trenches is performed by using the hard mask as an etch mask.
